(19) United States
(12) Patent Application Publication
(10) Pub. No.: US 2017/0330905 A1
(43) Pub. Date: Nov. 16, 2017

(54) IMAGE SENSOR

(71) Applicant: Samsung Electronics Co., Ltd., Suwon-si (KR)

(72) Inventors: Yong Suk Tak, Seoul (KR); Hong Bum Park, Seoul (KR); Won Oh Seo, Hwaseong-si (KR); Guk Hyon Yon, Hwaseong-si (KR); Ju Ri Lee, Yongin-si (KR)

(21) Appl. No.: 15/397,065

(22) Filed: Jan. 3, 2017

(30) Foreign Application Priority Data
May 13, 2016 (KR) 10-2016-0058973

(51) Int. Cl. H01L 27/146

(52) U.S. Cl. CPC H01L 27/1462; H01L 27/14621; H01L 27/14627

(57) ABSTRACT

A pixel array may include an array of microlenses, an array of photodetectors, and an array of color filters. The array of microlenses concentrate incoming light through respective filters in the array of color filters to respective photodetectors in the array of photodetectors. An anti-reflective layer is included between the photodetectors and color filters. The anti-reflective layer includes a first layer having a first index of refraction, a second layer closer to the color filter than the first layer having a second, higher, index of refraction, and a lattice adjusting layer between the first and second layers. The second layer includes a rutile phase TiO2 layer and the lattice adjusting layer includes a crystalline material having a lattice constant similar to that of the rutile phase TiO₂ layer.

### CROSS-REFERENCE TO RELATED APPLICATION

This application claims benefit of priority to Korean Patent Application No. 10-2016-0058973, filed on May 13, 2016 in the Korean Intellectual Property Office, the disclosure of which is incorporated herein by reference in its entirety.

### BACKGROUND

### 1. Field

Inventive concepts relate to an image sensor.

### 2. Description of Related Art

An image sensor is usually a semiconductor device that can convert an optical image into an electrical signal. Two frequently used types of image sensors are a charge-coupled device (CCD) and a complementary metal-oxide semiconductor (CMOS) device.

The CMOS image sensor may also be referred to as a CMOS image sensor (CIS). A CIS has a plurality of two-dimensionally arranged pixels (also referred to herein as an array of pixels). Each pixel includes a photoelectric conversion unit, or photodetector, such as a photodiode (PD). The photoelectric conversion unit functions to convert incident light into an electrical signal.

The incident light is received by the photoelectric conversion unit, typically through a color filter. In order to increase sensitivity, an anti-reflective layer, which can be made to have a high level of transmittance by adjusting its refractive index, may be placed between the color filter and the photoelectric conversion unit. However, a lower structure (for example, a metal wiring, made of, for example, copper (Cu)) of the CIS may hinder the possibilities of forming an optical layer, due to high temperature processing requirements that may be encountered in the formation of the optical layer.

### SUMMARY

Example embodiments of the present inventive concept may provide a high-sensitivity image sensor, which may have a high-refractive-index optical layer capable of low-temperature growth, and a method of manufacturing the same.

According to an example embodiment of inventive concepts, an image sensor may include: a semiconductor layer having a first surface, a second surface opposing the first surface, and a plurality of photoelectric conversion units configured to receive light from the second surface; an interconnecting layer disposed on the first surface of the semiconductor layer; an anti-reflective layer having a first layer disposed on the second surface of the semiconductor layer, the first layer having a first refractive index, a second layer disposed on the first surface, the second layer having a second refractive index higher than the first refractive index, wherein the second layer is formed of a rutile phase TiO₂ layer, and a lattice adjusting layer contacting at least one of an upper surface and a lower surface of the second layer and includes at least one of SnO₂, MoO₃, or Sb₂O₃; a buffer layer disposed on the anti-reflective layer; and a plurality of color filters disposed on the buffer layer.

According to an example embodiment of the present inventive concept, an image sensor may include: a semiconductor layer having a plurality of pixel regions, each of the plurality of pixel regions having a photoelectric conversion unit formed therein; an anti-reflective layer disposed on the semiconductor layer; and a plurality of color filters disposed on the anti-reflective layer, and disposed on the plurality of pixel regions, respectively. The anti-reflective layer may include a high-refractive-index optical layer disposed on the semiconductor layer including a TiO₂ layer having a refractive index of 2.6 or more, and a lattice adjusting layer contacting a surface of the high-refractive-index optical layer, and including crystals each having a lattice constant closer to a lattice constant of a rutile phase TiO₂ layer than to a lattice constant of an anatase phase TiO₂ layer.

In example embodiments in accordance with principles of inventive concepts, a pixel array includes an array of microlenses; an array of photodetectors; an array of color filters, wherein the array of microlenses concentrate incoming light through respective filters in the array of color filters to respective photodetectors in the array of photodetectors; and an anti-reflective layer between the photodetectors and color filters, the anti-reflective layer including a first layer having a first index of refraction, a second layer closer to the color filter than the first layer having a second, higher, index of refraction, and a lattice adjusting layer between the first and second layers, wherein the second layer includes a rutile phase TiO2 layer and the lattice adjusting layer includes a crystalline material having a lattice constant similar to that of the rutile phase TiO₂ layer.

### BRIEF DESCRIPTION OF DRAWINGS

The above, and other aspects, features, and advantages of the present disclosure will be more clearly understood from the following detailed description when taken in conjunction with the accompanying drawings, in which:

FIG. 1 is a schematic plan view of an image sensor according to an example embodiment;

FIG. 2 is a schematic cross-sectional view of the image sensor illustrated in FIG. 1;

FIG. 3 is an example of a circuit provided in a unit pixel of the image sensor illustrated in FIG. 1;

FIG. 4 is a layout of a unit pixel in which the circuit of FIG. 3 is provided in a semiconductor layer;

FIG. 5 is a cross-sectional view of an image sensor according to an example embodiment;

FIGS. 6 to 14 are cross-sectional views of a process of manufacturing the image sensor illustrated in FIG. 5;

FIG. 15 is a cross-sectional view of an image sensor according to an example embodiment;

FIG. 16 is a cross-sectional view of an image sensor according to an example embodiment;

FIGS. 17 to 22 are cross-sectional views of a process of manufacturing an image sensor according to an example embodiment;

FIGS. 23 to 28 are cross-sectional views of a process of manufacturing an image sensor according to an example embodiment;

FIG. 29 is a schematic perspective view of a camera module, including an image sensor, according to an example embodiment;

FIG. 30 is a schematic diagram of a mobile system, including an image sensor, according to an example embodiment; and

FIG. 31 is a schematic diagram of an electronic system, including an image sensor, according to an example embodiment.

### DETAILED DESCRIPTION

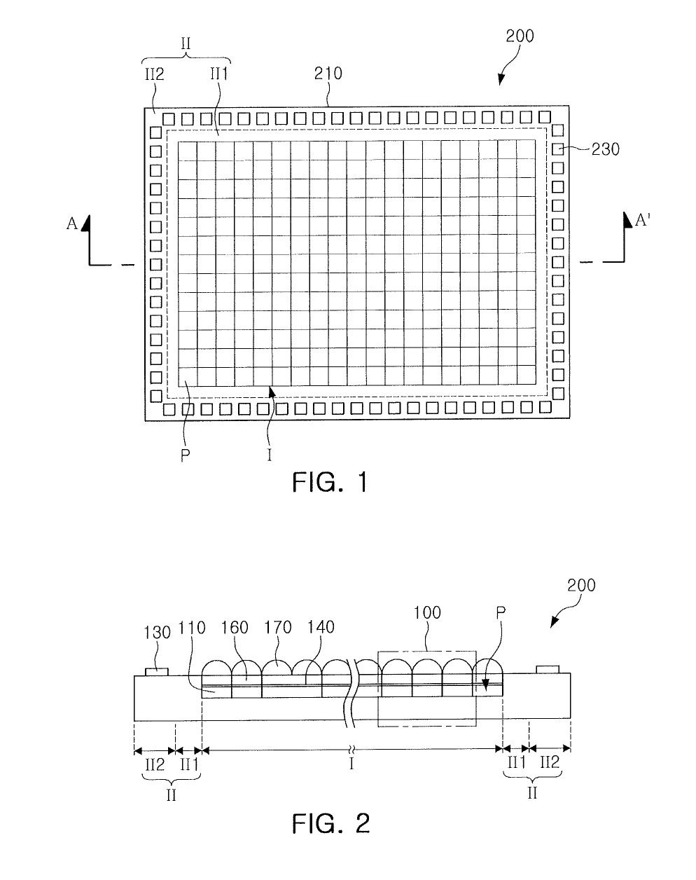

FIG. 1 is a schematic plan view of an image sensor according to an example embodiment of the present inventive concept. FIG. 2 is a schematic cross-sectional view of the image sensor illustrated in FIG. 1.

Referring to FIG. 1, an image sensor 200, according to an example embodiment, may include a sensor array region, also referred to herein as a pixel array region, I, and a peripheral circuit region II formed on a semiconductor substrate 210. In example embodiments, the peripheral circuit region II may include a logic region II1 and a pad region II2, and may define a region outside the pixel array region I on the semiconductor substrate 210 forming the image sensor 200.

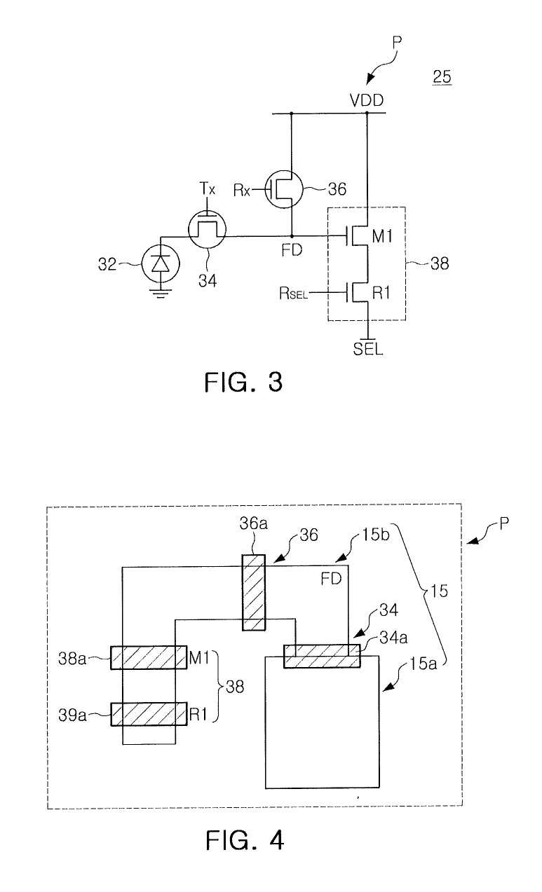

The pixel array region I may include a plurality of unit pixels P arranged in a matrix. Each of the unit pixels P may include a photodiode and transistors, for example. An example configuration of each of the unit pixels P will be described in more detail with reference to FIGS. 3 and 4.

As illustrated in FIG. 1, the logic region II1 may be disposed along four edges of the pixel array region I. The logic region II1 may be positioned along the four edges of the pixel array region I, but inventive concepts are not limited thereto, and logic region II1 may be disposed along two or three edges of the pixel array region I, for example.

The logic region II1 may be implemented as one or as a combination of electronic devices, including a plurality of transistors. The logic region II1. may be configured to provide an assigned signal to each of the unit pixels P of the pixel array region I, or to control an output signal to each of the unit pixels P. For example, the logic region II1 may include a timing generator, a row decoder, a column decoder, a row driver, a correlated double sampler (CDS), an analog to digital converter (ADC), or a latch. The pad region II2 may include a plurality of pads 130, and may be configured to transmit and receive an electrical signal to/from an external device, for example.

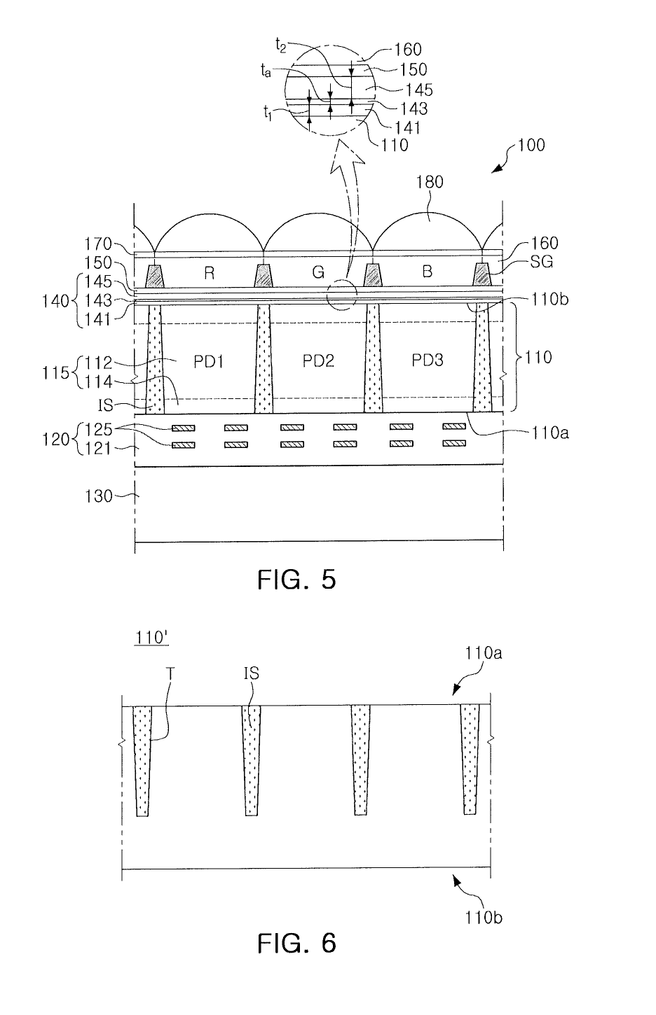

Each of the unit pixels P may be formed of a semiconductor layer 110 (refer to FIG. 5) and an interconnecting layer 120 (refer to FIG. 5) that may form the semiconductor substrate 210. For example, each of the unit pixels P may include a photoelectric conversion unit (for example, a photodiode) sensing light, a transfer transistor transferring charges generated by the photoelectric conversion unit, a reset transistor periodically resetting a floating diffusion (FD) region storing the transferred charges, and a source follower buffering a signal according to the charges stored in the FD region.

The configuration of each of the unit pixels P in an example embodiment will be described in detail with reference to FIGS. 3 and 4. FIG. 3 is an example of a circuit provided in a unit pixel of the image sensor illustrated in FIG. 1. FIG. 4 is a layout of a unit pixel, including a semiconductor layer, in which the circuit of FIG. 3 is implemented.

Referring to FIG. 3, each of the unit pixels P may include a photodiode 32 for sensing light, a transfer transistor Tx 34 transferring charges generated by the photodiode 32, a reset transistor Rx 36 periodically resetting an FD region storing the transferred charges, and a source follower 38 buffering a signal according to the charges stored in the FD region. The source follower 38 may include two metal oxide semiconductor (MOS) transistors Ml and R1 connected in series. An end of the reset transistor Rx 36 and an end of the MOS transistor M1 may be connected to a power supply voltage VDD, a gate electrode of the MOS transistor R1 may be connected to a row select line R_{SEL}, and an end of the MOS transistor R1 may be connected to a column select line SEL.

Each of the unit pixels P may be integrated on the semiconductor substrate 210. As illustrated in FIG. 4, an active region 15 may be formed on an upper portion of the semiconductor substrate 210, and may include a photodiode region 15a and a transistor region 15b. For example, the photodiode region 15a may have a quadrangular shape in each of the unit pixels P, as illustrated in FIG. 4. The transistor region 15b may have more of a linear shape, which contacts one surface of the photodiode region 15a, and of which at least a portion is bent, or having a right angle, as illustrated. The transistor region 15b may have agate electrode 34a of the transfer transistor Tx 34, a gate electrode 36a of the reset transistor Rx 36, and gate electrodes 38a and 39a of the source follower 38, formed therein.

Returning to FIG. 2, each of the unit pixels P may include color filters 160 (also referred to as a color filter layer 160) and microlenses 180 (also referred to as a microlens layer 180) sequentially disposed thereon. The color filters 160 may include, for example, red, green, and blue (RGB) filters. The color filters 160 may allow each of the unit pixels P to recognize a single color, that is, convert light from a specific region of an incoming spectrum to electrical energy, by sensing a separate component of incident light.

The unit pixels P and the color filters 160 may have an anti-reflective layer 140 disposed therebetween. The anti-reflective layer 140 may adjust a refractive index (n) of the pixel to suppress reflection of the light, thus ensuring a high level of transmittance of the light. The anti-reflective layer 140 may allow light, received through the color filters 160, to be incident to the photodiode 32 of each of the unit pixels P.

The anti-reflective layer 140, employed in an example embodiment, may include a titanium dioxide (TiO₂) layer having a high refractive index, in order to achieve a high level of transmittance. For example, the TiO₂ layer may have a refractive index of 2.6 or more, and a dominant crystal phase thereof may be a rutile phase. Such a TiO₂ layer may have a lattice adjusting layer disposed on a surface thereof. The lattice adjusting layer may allow rutile phase crystals to be obtained at a relatively low temperature by applying stress to a surface of an amorphous, or anatase, phase TiO₂ layer. For example, a rutile phase TiO₂ layer may be obtained at about 500° C. or below, and further, at about 400° C. or below. Configuration of the rutile phase TiO₂ layer will be described in more detail with reference to FIG. 5.

FIG. 5 is a cross-sectional view of an image sensor according to an example embodiment of inventive concepts, and may also be understood as an enlarged cross-sectional view of region A of the image sensor illustrated in FIG. 2. For convenience of description, the contents of FIG. 5, described in the descriptions of FIGS. 1 through 4, will not be repeated here in detail.

Referring to FIG. 5, an image sensor 100 may include a semiconductor layer 110, interconnecting layer 120, carrier substrate 130, anti-reflective layer 140, color filter layer 160, and microlens layer 180. The image sensor 100 may further include a buffer layer 150 (also referred to as a lower flat layer 150) disposed in a space between the anti-reflective layer 140 and the color filter layer 160, and a planarizing layer 170 (also referred to as an upper flat layer 170) disposed in a space between the color filter layer 160 and the microlens layer 180.

The semiconductor layer 110 may contain, for example, silicon (Si). However, inventive concept are not limited thereto, and the semiconductor layer 110 may include a semiconductor element, such as germanium (Ge), a semiconductor compound, such as SiC, GaAs, InAs, or InP, a silicon on insulator (SOI) structure, or a buried oxide (BOX) layer, for example.

The semiconductor layer 110 may include a first surface 110a and a second surface 110b opposing the first surface 110a. The first surface 110a and the second surface 110b may also be referred to herein as a lower surface and an upper surface of the semiconductor layer 110, respectively. The first surface 110a of the semiconductor layer 110 may have the interconnecting layer 120 disposed thereon, and light may be received through the second surface 110b of the semiconductor layer 110.

The semiconductor layer 110 may be a silicon substrate or an epitaxial layer formed on a silicon substrate, for example. The semiconductor layer 110 may have a plurality of photoelectric conversion devices, such as PD1, PD2, and PD3 formed therein, and denoted as 115. The photoelectric conversion devices 115 may generate a photoelectron in response to light received through the second surface 110b. Each of the photoelectric conversion devices 115 may be implemented as a photodiode, a phototransistor, a photogate, or a pinned photodiode, for example.

In an example embodiment, each of the photoelectric conversion devices 115 may include a first impurity region 112 positioned inside the semiconductor layer 110, and a second impurity region 114 positioned close to or abutting on the first surface 110a of the semiconductor layer 110. Adjacent photoelectric conversion devices 115 may have a pixel separator IS disposed in a space therebetween. The photoelectric conversion devices 115 may be separated from each other by the pixel separator IS. The pixel separator IS may be formed in two-dimensional mesh form, for example, and may be formed by filling a deep trench, passing from the first surface 110a to the second surface 110b of the semiconductor layer 110, with an insulating material, such as an oxide. The pixel separator IS may be a material having a refractive index lower than that of a material forming the semiconductor layer 110.

The pixel separator IS, employed in an example embodiment, may be formed in the deep trench to thereby effectively reduce optical crosstalk and electrical crosstalk. The term “optical crosstalk,” as used herein, may refer to a phenomenon in which light, received through the color filter layer 160, is transmitted to an adjacent photoelectric conversion device, and the term “electrical crosstalk,” as used herein, may refer to a phenomenon in which a pair of electron holes, generated in a depletion region of a photoelectric conversion device, is transmitted to an adjacent light sensing device.

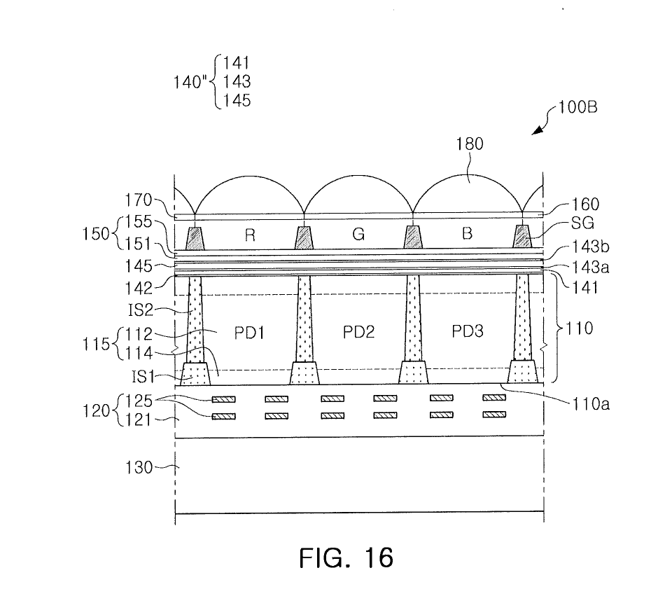

In example embodiments, the pixel separator IS may include a shallow trench isolation (STI) portion separating the photoelectric conversion devices 115 in the active region, and may also include a deep trench isolation (DTI) portion surrounding each of the unit pixels P, along with the STI portion (refer to FIG. 16).

The interconnecting layer 120 may be disposed on the first surface 110a of the semiconductor layer 110. The interconnecting layer 120 may include an interlayer insulating layer 121 and wirings 125. For example, the interlayer insulating layer 121 may include an oxide layer, such as a silicon oxide, or a composite layer of an oxide layer and a nitride layer. The wirings 125 may be provided as electrical wirings for sensing operations of the photoelectric conversion devices 115 formed in the semiconductor layer 110, or of the transfer transistor Tx 34 and the reset transistor Rx 36, illustrated in FIGS. 3 and 4, for example. The wirings 125 may include multiple layers, and may be divided into a gate- or word-line level wiring and a bit-line level wiring.

In some example embodiments, the wirings 125 may be utilized to reflect light received through the photoelectric conversion devices 115 back to the photoelectric conversion devices 115. Each of the wirings 125 may include a metal, such as copper (Cu), titanium (Ti), tungsten (W), or a titanium nitride. A low melting point metal wiring, such as a commonly used copper (Cu) wiring, may be a limiting factor of a temperature applied to a follow-up process, and may be an obstacle to the design of an optical structure, such as an anti-reflective layer 140, requiring a high level of refractive index. However, example embodiments in accordance with principles of inventive concepts overcome such limitations, as described in greater detail below.

The semiconductor layer 110 may include the anti-reflective layer 140 formed on the second surface 110b thereof. The anti-reflective layer 140 may adjust a refractive index of a color filter layer 160 such that light received through the color filter layer 160 may travel to the photoelectric conversion devices 115 with a high level of transmittance.

The anti-reflective layer 140, employed in an example embodiment, may include a first layer 141 and a second layer 145 having different refractive indexes, and may be coupled to have an appropriate thickness to achieve a high level of transmittance.

The first layer 141 may be disposed on the second surface 110b of the semiconductor layer 110, and may have a first refractive index. The second layer 145 may be disposed on the first layer 141, may have a second refractive index higher than the first refractive index, and may include a rutile phase TiO₂ layer.

In an example embodiment, the first layer 141 may be a fixed charge layer generating negative fixed charges. Such a fixed charge layer may cause hole accumulation to occur on the second surface 110b of the semiconductor layer 110, thereby effectively reducing the occurrence of a dark current and, accordingly, the number of white spots. The first layer 141 may include a metal oxide layer or a metal fluoride layer including oxygen or fluorine in an amount less than the stoicheiometric quantity of oxygen or fluorine.

For example, the first layer 141 may include a metal oxide or a metal fluoride including at least one of hafnium (HF), zirconium (Zr), aluminum (Al), tantalum (Ta), titanium (Ti), yttrium (Y), or lanthanum (La).

The first and second layers 141 and 145 may be appropriately designed to increase transmittance thereof. For example, the thickness t₁ of the first layer 141 may range from about 1 nm to about 50 nm, and the thickness t₂ of the second layer 145 may range from about 20 nm to about 100 nm. In example embodiments, when the first layer 141 includes an Al₂O₃ layer (n=1.63), a high transmittance of 98% or more may be achieved. In example embodiments, when the thickness t₁ of the first layer 141 (also referred to as an Al₂O₃ layer 141) ranges from about 1 nm to about 15 nm, and the thickness t₂ of the second layer 145 (also referred to as a TiO₂ layer 145) ranges from about 40 nm to about 60 nm, a high transmittance of 99% or more may be achieved.

The rutile phase TiO₂ layer employed in the second layer 145 may have a refractive index of about 2.78 or higher, which is higher than a refractive index (about 2.5) of an anatase phase TiO₂ layer (@500 nm). However, a high temperature of 800° C. or more may be required to recrystallize the anatase phase TiO₂ layer into a rutile phase TiO₂ layer. In the case of crystallizing an amorphous TiO₂ layer, the amorphous TiO₂ layer may be crystallized at a temperature of 800° C. or less, but a heat treatment at a high temperature of 500° C. or greater may be required to perform the crystallization process. In fact, a heat treatment at a temperature of 650° C. or more may be required to obtain a refractive index (n) of up to 2.78. Such a high temperature may cause serious damage to another configuration, or other components, of an image sensor, in particular, to a metal wiring, such as a copper (Cu) wiring, as described above, and may thus be a significant limitation on the use of a high-refractive-index optical layer.

In accordance with principles of inventive concepts, in order to form a rutile phase TiO₂ layer at a low temperature, one that will not damage other components of the image sensor, the anti-reflective layer 140 may further include a lattice adjusting layer 143 disposed in a space between the first layer 141 and the second layer 145 so as to contact a lower surface of the second layer 145. The lattice adjusting layer 143 may include a crystalline material having a lattice constant similar to that of the rutile phase TiO₂ layer.

In detail, a TiO₂ layer (for example, an anatase phase TiO₂ layer or an amorphous TiO₂ layer) may be grown at a low temperature, using a surface of the lattice adjusting layer 143, having a lattice constant similar to that of the rutile phase TiO₂ layer, as a crystal growth plane, which causes stress due to lattice mismatching. In order to reduce the stress, the TiO₂ layer can be grown into a rutile phase TiO₂ layer, even at a low temperature. For example, even when the TiO₂ layer is deposited at about 500° C. or below, and, even more advantageously, about 400° C. or below, the TiO₂ layer can be grown into a rutile phase TiO₂ layer having a high level of refractive index by virtue of the lattice adjusting layer 143. In accordance with principles of inventive concepts, the components 141, 143, and 145 of the anti-reflective layer 140 maybe formed using a low-temperature deposition process, such as atomic layer deposition (ALD).

The lattice constant and crystal structure of the lattice adjusting layer 143 may increase the effect of such lattice matching as they get closer to the lattice constant and crystal structure of the rutile phase TiO₂ layer. However, even when lattice constants of the lattice adjusting layer 143, at partial axes of the lattice adjusting layer 143, are rather different, or crystal structures of the lattice adjusting layer 143 at the partial axes are somewhat different, a crystal growth plane of the lattice adjusting layer 143 may be appropriately selected to obtain a desired effect.

Additionally, in example embodiments in which the lattice adjusting layer 143 has a lattice constant closer to the lattice constant of the rutile phase TiO₂ layer than to the lattice constant of the anatase phase TiO₂ layer on a crystal axis of the surface of the lattice adjusting layer 143, even when the TiO₂ layer is grown at a low temperature, a desired rutile phase TiO2 layer can be obtained.

In example embodiments, lattice adjusting layer 143 may include a material that may ensure a sufficient degree of light transmitting properties. A thickness of the lattice adjusting layer 143 may range from about 0.5 nm to about 5 nm.

As such, the lattice adjusting layer 143 may have a relatively reduced thickness, and may thus have a less disadvantageous influence, in terms of optics. However, even when the lattice adjusting layer 143 has a lattice constant similar to that of the rutile phase TiO₂ layer, in a case in which the lattice adjusting layer 143 is an opaque material, such as a black material, the thickness of the lattice adjusting layer 143 may be limited.

In view of these conditions, in example embodiments the lattice adjusting layer 143 may include at least one of SnO₂, MoO₃, and Sb₂O₃.

TABLE 1

| | Rutile | Anatase | | | |
|---|---|---|---|---|---|
| Division | TiO₂ | TiO₂ | SnO₂ | MoO₃ | Sb₂O₃ |
| Crystal | Tetragonal | Tetragonal | Tetragonal | Layer structure | Rhombohedragonal |
| Lattice | a = 4.59 | a = 3.78 | a = 4.73 | a = 3.96 | a = 4.92 |
| constant | c = 2.95 | c = 9.51 | c = 3.18 | b = 13.85 | b = 12.46 |
| | | | | c = 3.69 | c = 5.42 |

A TiO₂ layer forming the second layer 145 does not need to be a purely rutile phase TiO₂ layer. For example, even when an amorphous TiO₂ layer or another phase TiO₂ layer is present in a portion of the TiO₂ layer, the TiO₂ layer may primarily include a rutile phase TiO₂ layer. In this respect, the second layer 145, according to an example embodiment, maybe defined by a refractive index. For example, the second layer 145 may be defined as having a refractive index of about 2.6 and may include a rutile phase TiO₂ layer.

The color filter layer 160 may have a partition SG, allowing light of wavelengths in the visible spectrum to pass therethrough, and may separate the unit pixels P, disposed in the space between the color filters 160, from each other, thus minimizing optical interference, if necessary. For example, the color filter layer 160 may be in the Bayer pattern, having a red filter R, a green filter G, and a blue filter B, in each of the unit pixels P. The red filter R may allow wavelengths of light from within the red region of the visible spectrum to pass therethrough. The green filter G may allow wavelengths of light from within the green region of the visible spectrum to pass therethrough. The blue filter B may allow wavelengths of light from within the blue region of the visible spectrum to pass therethrough.

In an example embodiment, the color filter layer 160 may be a cyan filter, a magenta filter, or a yellow filter. The cyan filter may allow wavelengths of light of 450 nm to 550 nm from within the light in the visible spectrum to pass therethrough. The magenta filter may allow wavelengths of light of 400 nm to 480 nm from within the light in the visible spectrum to pass therethrough. The yellow filter may allow wavelengths of light of 500 nm to 600 nm from within the light in the visible spectrum to pass therethrough.

Buffer layer 150 may be disposed in a space between the anti-reflective layer 140 and the color filter layer 160, and the planarizing layer 170 may be disposed in a space between the color filter layer 160 and the microlens layer 180. The buffer layer 150 may remove a stepped portion to form a flat surface, and may also be referred to as the lower flat layer. The planarizing layer 170 may also be referred to as the upper flat layer.

Both the buffer layer 150 and the planarizing layer 170 may be formed of a material having a refractive index higher than that of a silicon oxide. However, the buffer layer 150 and the planarizing layer 170 are not limited thereto, and may include, for example, at least one of SiO₂, SiON, Al₂O₃, HfO₂, Ta₂O₅, and ZrO₂, while also including multiple layers that include different materials.

The microlens layer 180 may concentrate externally received light. In some example embodiments, the image sensor 100 may be implemented without the microlens layer 180.

FIGS. 6 through 14 are cross-sectional views of an example of a process of manufacturing the image sensor illustrated in FIG. 5.

As illustrated in FIG. 6, a semiconductor layer 110′, having the first surface 110a and the second surface 110b opposing each other, and having the pixel separator IS, may be formed.

The semiconductor layer 110′ may include a silicon substrate, the first surface 110a may be the front of the silicon substrate, that is, the surface to which a semiconductor process is applied, and the second surface 110b may be the rear of the silicon substrate prior to grinding of the semiconductor layer 110′.

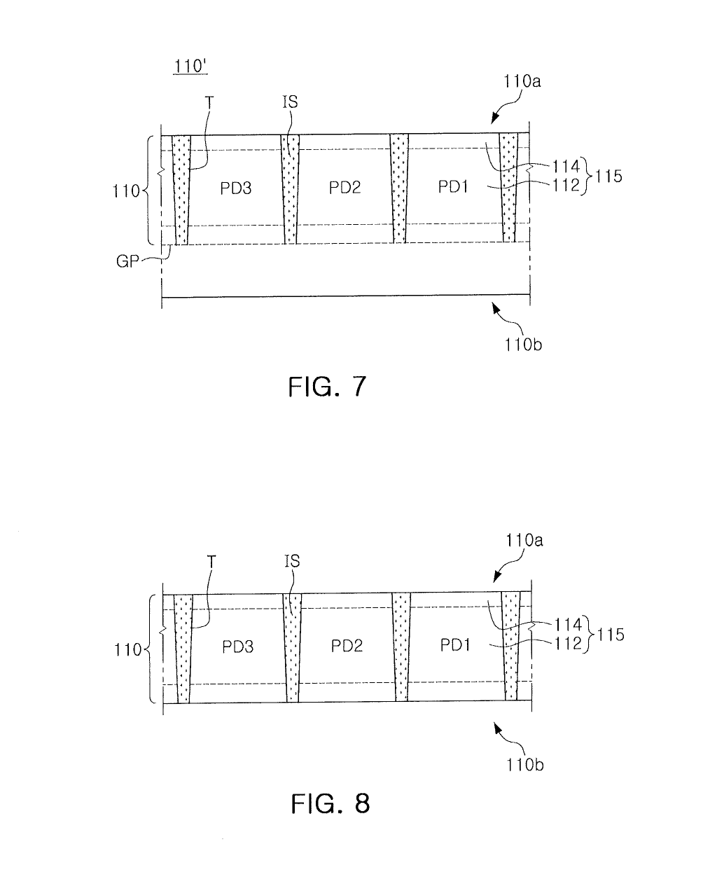

Using a mask pattern, a trench T may be formed, running from the first surface 110a to the second surface 110b in the first surface 110a of the semiconductor layer 110′, and then may be filled with an insulating material to form the pixel separator IS. In this process, the pixel separator IS may be formed so as not to pass through the semiconductor layer 110′, and the second surface 110b may be ground in a follow-up process to expose the pixel separator IS to the second surface 110b, thus forming the pixel separator IS, as illustrated in FIG. 5. A trench may be formed through a semiconductor layer, and, in an example embodiment, a pixel separator having a through structure may also be formed. As illustrated in FIG. 7, the photoelectric conversion devices 115 (also referred to as photodiodes 115) may be formed in the semiconductor layer 110′, separated by the pixel separator IS.

Using an impurity doping process, the photodiodes 115 may be formed as photoelectric conversion devices. In detail, each of the photoelectric conversion devices 115 may include the first impurity region 112 (for example, containing a p-type impurity), positioned inside the semiconductor layer 110′, and the second impurity region 114 (for example, containing an n-type impurity), positioned close to or abutting on the first surface 110a of the semiconductor layer 110′. In accordance with principles of inventive concepts, other photoelectric conversion devices, such as a phototransistor, a photogate, or a pinned photodiode, may also be implemented.

As illustrated in FIG. 8, the second surface 110b of the semiconductor layer 110′ may be ground to have a desired thickness of the semiconductor layer 110′. In this process, the semiconductor layer 110 may be ground up to a part thereof indicated by “GP” such that the pixel separator IS maybe exposed through the second surface 110b of the semiconductor layer 110.

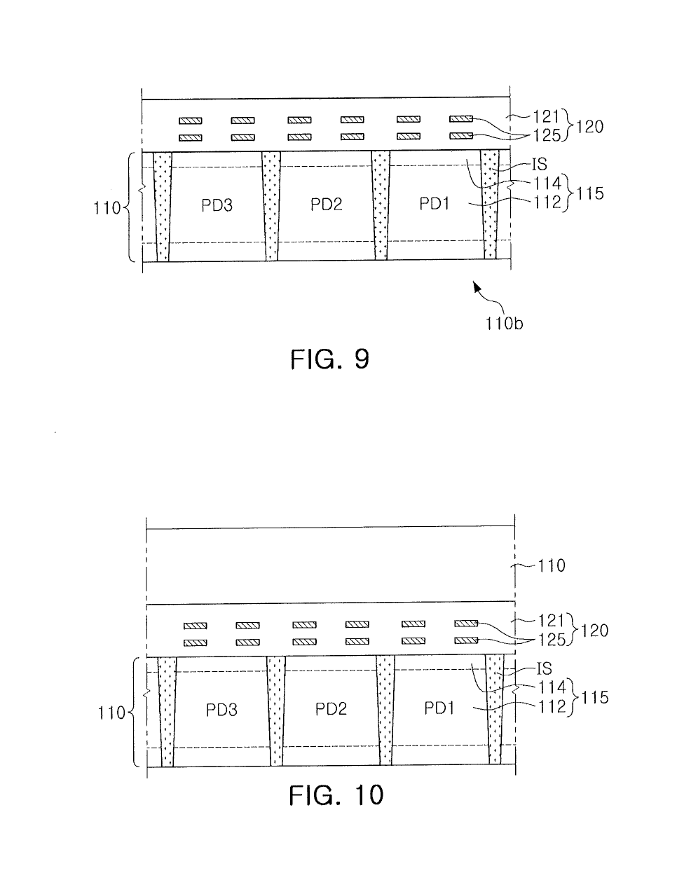

As illustrated in FIG. 9, the interconnecting layer 120 may be formed on the first surface 110a of the semiconductor layer 110.

The interconnecting layer 120, formed in this process, may include the interlayer insulating layer 121 and the wirings 125. In example embodiments, the interlayer insulating layer 121 may include an oxide layer, such as a silicon oxide, or a composite layer of an oxide layer and a nitride layer. Each of the wirings 125 may include a metal, such as copper (Cu), titanium (Ti), tungsten (W), or a titanium nitride. The wirings 125, formed in this process, may be divided into a gate- or word-line level wiring, and a bit-line level wiring, for example.

As illustrated in FIG. 10, the carrier substrate 130 may be bonded to the interconnecting layer 120. Then, a process of forming the anti-reflective layer 140 on the second surface 110b of the semiconductor layer 110 maybe performed such that light maybe easily received by the photoelectric conversion devices 115.

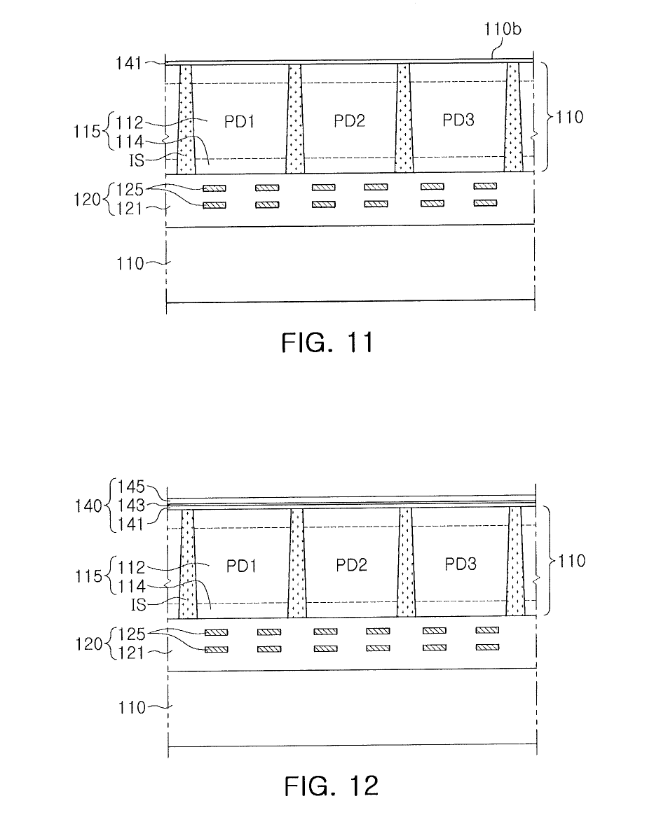

As first illustrated in FIG. 11, the first layer 141, having the first refractive index, may be formed on the second surface 110b of the semiconductor layer 110. The first layer 141 may be an Al₂O₃ layer. The first layer 141 may be a fixed charge layer generating negative fixed charges. For example, the first layer 141 may include a metal oxide or a metal fluoride including at least one of hafnium (HF), zirconium (Zr), aluminum (Al), tantalum (Ta), titanium (Ti), yttrium (Y), and lanthanum (La). The thickness of the first layer 141 may range from about 1 nm to about 50 nm. In some example embodiments, prior to the formation of the first layer 141, the second surface 110b of the semiconductor layer 110 may be subjected to an oxygen plasma treatment to thus reduce a surface defect density of the second surface 110b and prevent diffusion of any metal element (for example, aluminum (Al)) of the first layer 141.

As illustrated in FIG. 12, the lattice adjusting layer 143 and the second layer 145, the TiO₂ layer, may be sequentially formed on the first layer 141.

In accordance with principles of inventive concepts, lattice adjusting layer 143 may include a crystalline material having a lattice constant similar to that of the rutile phase TiO₂ layer. For example, the lattice adjusting layer 143 may include at least one of SnO₂, MoO₃, and Sb₂O₃. The lattice adjusting layer 143 may also include a material that may ensure a sufficient degree of light transmitting properties. The thickness of the lattice adjusting layer 143 may range from about 0.5 nm to about 5 nm.

The TiO₂ layer, the second layer 145, may be formed on the lattice adjusting layer 143, having a lattice constant and a lattice structure similar to those of the rutile phase TiO₂ layer. The second layer 145 may thus be grown into a rutile phase TiO₂ layer, even in a low-temperature growth process. Such a growth process may be an ALD process, whereby the second layer 145, the rutile phase TiO₂ layer, may be formed at about 500° C. or below, and, possibly more advantageously, about 400° C. or below. The second layer 145 may be grown to have a thickness of from about 20 nm to about 100 nm. In this operation, lattice matching with the lattice adjusting layer 143 may allow an optical layer having a high refractive index of about 2.6 or more, that may not be obtained from the anatase phase TiO₂ layer, to be formed. As a result, in accordance with principles of inventive concepts, an excellent anti-reflective layer 140 having a high level of transmittance (for example, about 98% or more) may be formed at a low temperature: a temperature at which damage to other components, such as a metal wiring or the like, does not occur.

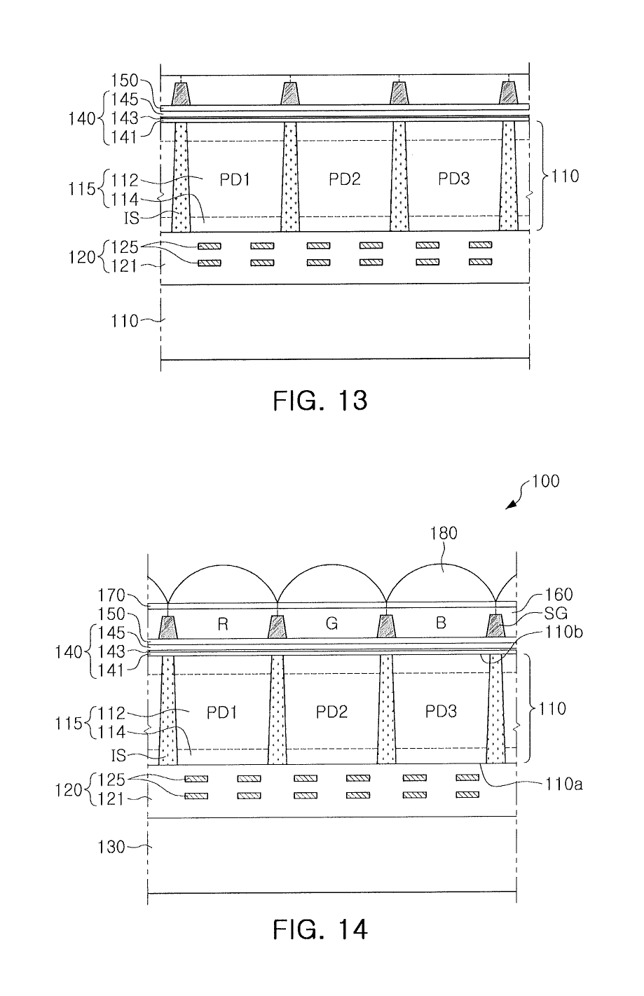

As illustrated in FIG. 13, the buffer layer 150 may be formed on the anti-reflective layer 140, and the color filter layer 160 having the partition SG may be formed on the buffer layer 150. The partition SG may be provided in a matrix, in which each unit pixel region is divided, and may be configured to prevent mutual interference between the adjacent color filters 160, denoted by R, G, and B.

As illustrated in FIG. 14, the planarizing layer 170 may be formed on the color filter layer 160, and the microlens layer 180 may be formed on the planarizing layer 170.

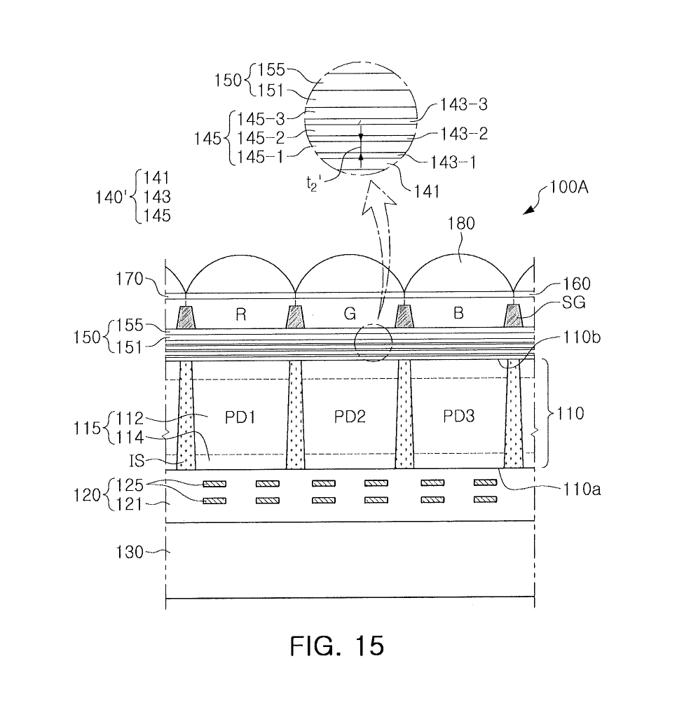

In the foregoing example embodiment, the lattice adjusting layer 143 may be exemplified as being positioned on a lower surface of the TiO₂ layer, but inventive concepts are not limited thereto. For example, the lattice adjusting layer 143 may be interposed in a space between TiO₂ layers (refer to FIG. 15), or positioned on another surface of the TiO₂ layers (for example, an upper surface or lateral surface of the TiO₂ layer) (refer to FIGS. 16, 23, and 28)

FIG. 15 is a cross-sectional view of an image sensor according to an example embodiment in accordance with principles of inventive concepts.

Referring to FIG. 15, an image sensor 100A may be understood as being similar to the image sensor 100 illustrated in FIG. 5, except for a structure of an anti-reflective layer 140′. A component according to an example embodiment may be understood with reference to a description of the same or a similar component of the image sensor 100, illustrated in FIG. 5, unless otherwise specified.

The image sensor 100A, according to an example embodiment, may include the anti-reflective layer 140′, in which a plurality of lattice adjusting layers 143-1, 143-2, and 143-3 and a plurality of second layers 145-1, 145-2, and 145-3 are alternately stacked on each other.

When a lattice adjusting layer is employed, if a TiO₂ layer is grown to have a certain thickness or greater (for example, a threshold thickness), the beneficial effects of the lattice adjusting layer positioned below the TiO₂ layer may be reduced, so that the TiO₂ layer may be polycrystallized. As a result, it may be difficult to form a high-refractive-index layer having a relatively large thickness.

In an example embodiment, when the second layer 145-1 is formed on the lattice adjusting layer 143-1 to have a thickness t₂′, less than or equal to a threshold thickness, the lattice adjusting layers 143-2 and 143-3 and the second layers 145-2 and 145-3 may be additionally and repeatedly formed, and the second layer 145, having a substantially sufficient thickness, may thus be formed. In accordance with principles of inventive concepts, such an arrangement may allow the thickness of the rutile phase TiO₂ layer forming the second layer 145 to be increased, or the degree of impurity of rutile phase TiO₂ contained in the second layer 145 to be increased.

FIG. 16 is a cross-sectional view of an image sensor according to an example embodiment of inventive concepts.

Referring to FIG. 16, an image sensor 100B according to an example embodiment may be understood as being similar to the image sensor 100 illustrated in FIG. 5, except for a structure of an anti-reflective layer 140″, a first pixel separator IS1, and a second pixel separator IS2. A component according to an example embodiment may be understood with reference to a description of the same or a similar component of the image sensor 100 illustrated in FIG. 5, unless otherwise specified (that is, a detailed description of components will not be repeated here).

The image sensor 100B, according to an example embodiment, may include the second layer 145, and a lower lattice adjusting layer 143a and an upper lattice adjusting layer 143b disposed on an upper surface and a lower surface of the second layer 145. In this structure, a rutile phase TiO₂ layer may be formed from the upper surface of the second layer 145 through lattice matching by additionally disposing the upper lattice adjusting layer 143b on the upper surface of the second layer 145. In an example process, a TiO₂ layer may be formed by forming and then removing a dummy pattern layer in a space between the lower and upper lattice adjusting layers 143a and 143b illustrated in FIG. 16, and by filling the space. In this manner, in accordance with principles of inventive concepts the rutile phase TiO₂ layer may be formed at a relatively low temperature, thereby forming an anti-reflective layer without damaging or otherwise disturbing other components that may be so-damaged if the anti-reflective layer were implemented using a conventional, higher-temperature process.

In an example embodiment, a pixel separator may include, unlike in the foregoing example embodiment, the first pixel separator IS1, which is a shallow device separator, and the second pixel separator IS2, which is a deep device separator. The first pixel separator IS1 may be formed from the second surface 110b to define the active region 15. The unit pixel regions may be separated from each other by the second pixel separator IS2. The second pixel separator IS2 may extend from the first pixel separator IS1 to the second surface 110b. The second pixel separator IS2 may be formed in two-dimensional mesh form. The second pixel separator IS2 may have a structure in which the second pixel separator IS2 may surround each of the unit pixel regions, and may prevent crosstalk between adjacent unit pixels P, for example.

As illustrated in FIGS. 15 and 16, use of the dummy pattern layer may allow the lattice adjusting layers 143-1, 143-2, and 143-3 or 143a and 143b to be provided on the upper surface or the lateral surface of the TiO₂ layer, as well as on the lower surface of the TiO₂ layer, when the TiO₂ layer is grown. A method of manufacturing an image sensor according to an example embodiment to be described below may include a process of providing an additional lattice adjusting layer on the lateral surface of the second layer 145, or on the lateral and upper surfaces of the second layer 145, as well as on the lower surface of the second layer 145.

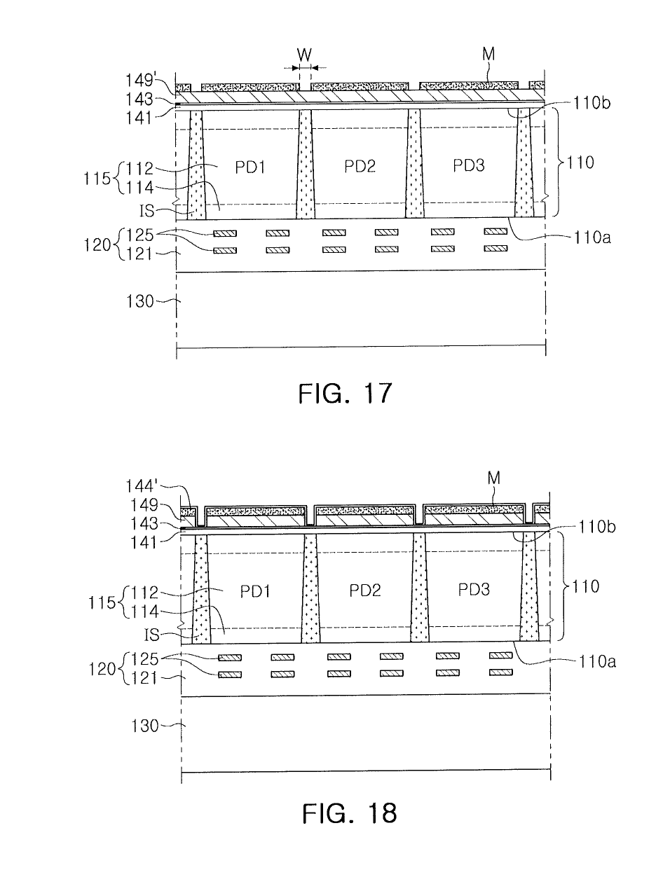

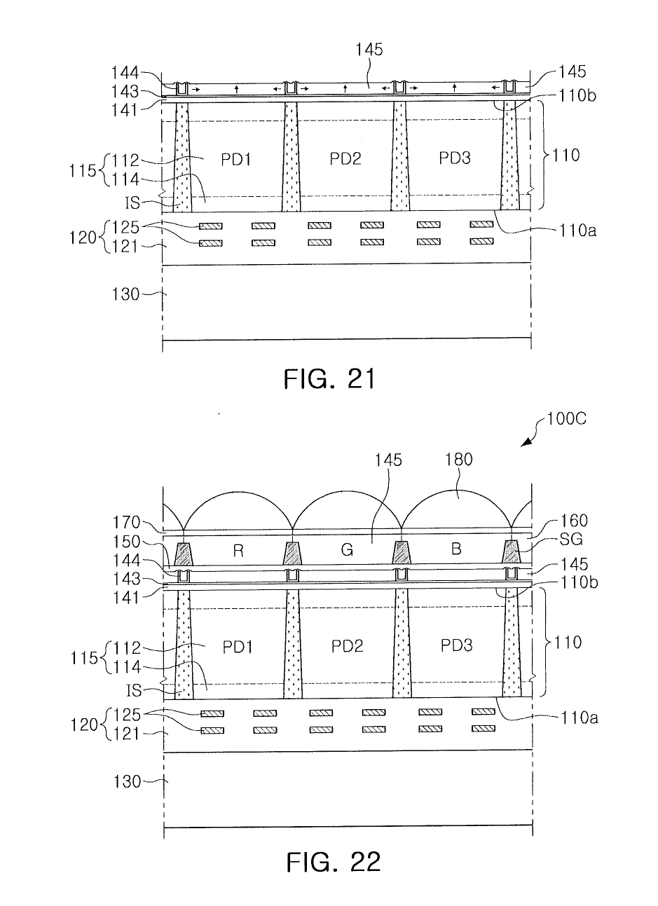

FIGS. 17, 18, 19, 20, 21, and 22 are cross-sectional views of a process of manufacturing an image sensor according to an example embodiment of inventive concepts. The process, illustrated in FIG. 17, may be understood as a process that takes place after the first layer 141 illustrated in FIG. 11 is formed.

Referring to FIG. 17, a first lattice adjusting layer 143 may be formed on the first layer 141, and a dummy layer 149′ may be formed on the first lattice adjusting layer 143. In order to pattern the dummy layer 149′, mask patterns M may be formed on the dummy layer 149 ′.

The dummy layer 149′ may be formed from a material having an etch selectivity different from that of layers to be formed in a follow-up process. For example, the dummy layer 149′ may include a nitride, such as a silicon nitride. In this process, a portion of the dummy layer 149′, positioned in a space between the mask patterns M, may be removed. In this manner, a width W of the space between the mask patterns M may be set, such that the portion of the dummy layer 149′ to be removed may be positioned within a region that does not allow the incidence of light.

In some example embodiments, a light blocking portion may be formed in the space between the mask patterns M in a follow-up process.

As illustrated in FIG. 18, a dummy pattern 149 may be formed by selectively removing the dummy layer 149′ by using the mask patterns M, and a material layer 144′ for a second lattice adjusting layer 144 may be formed.

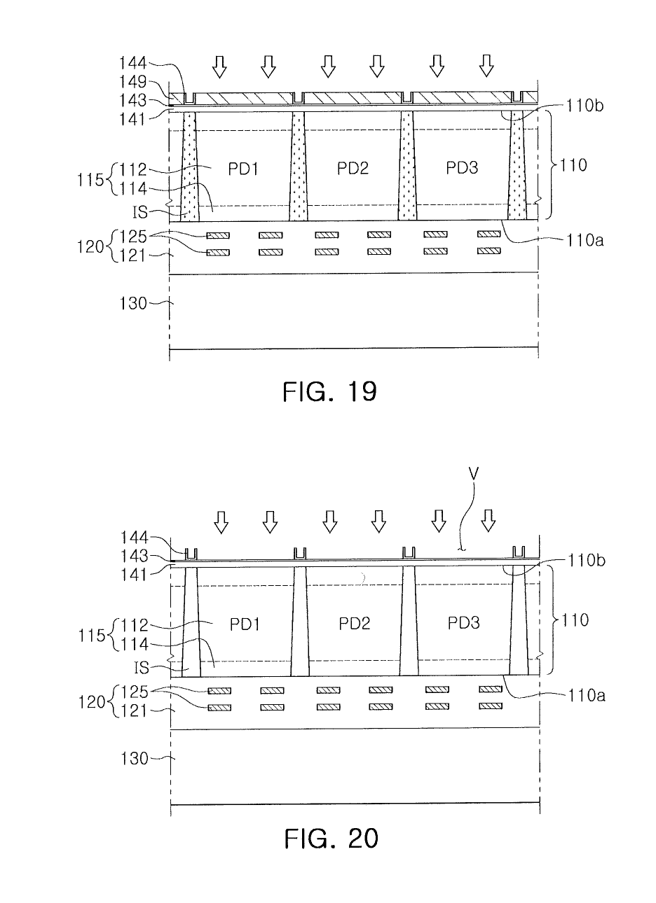

The material layer 144′ may be formed on surfaces of the mask patterns M, as well as on a lateral surface of the dummy pattern 149, while the mask patterns M remain. The material layer 144′ may include a material having a lattice constant similar to that of the rutile phase TiO₂ layer, as in the first lattice adjusting layer 143. In an example embodiment, the second lattice adjusting layer 144 may be disposed only on the lateral surface of the dummy pattern 149 (refer to FIG. 19), and light transmitting properties featured in the forgoing example embodiment may, therefore, not be required, because light need not be transmitted though the lateral surfaces. As a result, for example, the material layer 144′ for the second lattice adjusting layer 144 may also include a black material, such as RuO₂, in addition to SnO₂, MoO₃, and Sb₂O₃.

As illustrated in FIG. 19, portions of the material layer 144′, positioned on the surfaces of the mask patterns M, may be removed by eliminating the mask patterns M.

This process may allow portions of the material layer 144′, positioned in spaces between portions of the dummy pattern 149, to remain, and the portions of the material layer 144′ may be provided as the second lattice adjusting layer 144 for the second layer 145 (for example, a rutile phase TiO₂ layer) to be formed in a follow-up process. The second lattice adjusting layer 144 may contact the lateral surface of the second layer 145. In example embodiments in which the second lattice adjusting layer 144 is formed of a black material, such as RuO₂, the second lattice adjusting layer 144 may function as a light blocking portion in a space between the unit pixels P.

As illustrated in FIG. 20, a space V, defined by the first and second lattice adjusting layers 143 and 144, may be provided by removing the dummy pattern 149.

As illustrated in the foregoing example embodiment, the first lattice adjusting layer 143 may provide a deposition surface for lattice matching, which is a lower surface of the first lattice adjusting layer 143, and the second lattice adjusting layer 144 may provide additional deposition surfaces for lattice matching, which are lateral surfaces of the second lattice adjusting layer 144.

Subsequently, a TiO₂ layer may be deposited in the space V defined by the first and second lattice adjusting layers 143 and 144. As indicated by an arrow, the first lattice adjusting layer 143 and the second lattice adjusting layer 144 may enable a rutile phase TiO₂ layer to be grown from the lower surface of a deposited TiO2 layer and the lateral surfaces of the deposited TiO₂ layer through lattice matching, respectively.

As illustrated in FIG. 22, an image sensor 100C, according to an example embodiment, may be manufactured by sequentially forming the buffer layer 150, the color filter layer 160, the planarizing layer 170, and the microlens layer 180. In example embodiments, the buffer layer 150 may be utilized to planarize a somewhat uneven surface of the deposited TiO₂ layer caused by the second lattice adjusting layer 144.

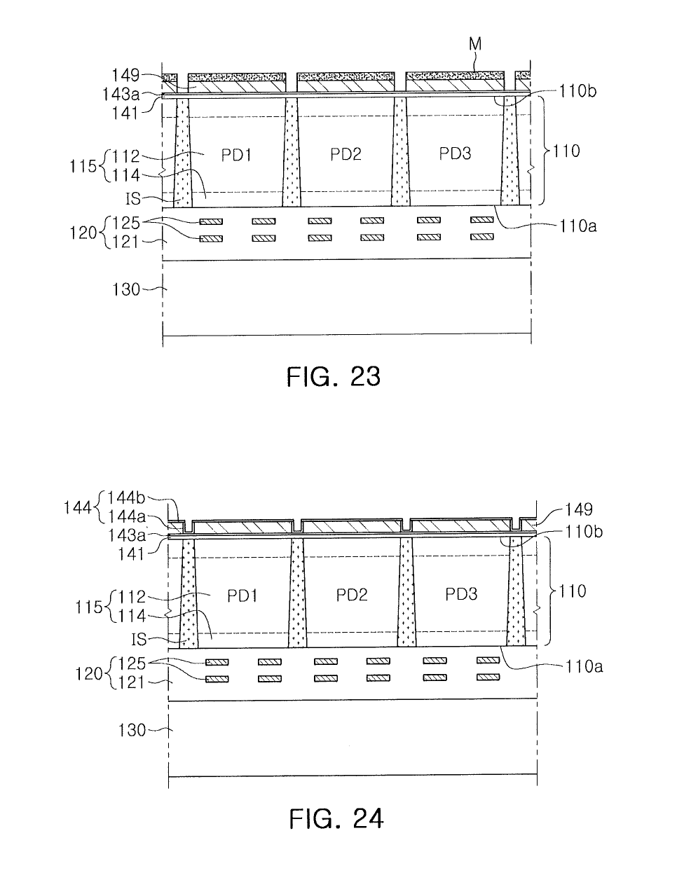

FIGS. 23, 24, 25, 26, 27, and 28 are cross-sectional views of a process of manufacturing an image sensor according to an example embodiment of inventive concepts.

FIG. 23 illustrates a process that may be implemented between the process illustrated in FIG. 17 and the process illustrated in FIG. 18, for example, a process before forming the material layer 144′ of FIG. 18 after forming the dummy pattern 149 by using the mask patterns M.

In an example embodiment, as illustrated in FIG. 23, the mask patterns M, used in the formation of the dummy pattern 149, may be removed. The process of removing the mask patterns M may be performed before the formation of the material layer 144′ of FIG. 18, unlike in the previous example embodiment.

As illustrated in FIG. 24, the second lattice adjusting layer 144 may be formed on the dummy pattern 149.

The second lattice adjusting layer 144, employed in an example embodiment, may include, unlike the previous example embodiment, upper regions 144b, provided on upper surfaces of the portions of the dummy pattern 149, as well as lateral regions 144a, provided on portions of the second lattice adjusting layer 144 positioned in the space between the portions of dummy pattern 149, that is, the lateral surfaces of the portions of the dummy pattern 149. The second lattice adjusting layer 144 may include a material having a lattice constant similar to that of the rutile phase TiO₂ layer, as illustrated in the previous example embodiment.

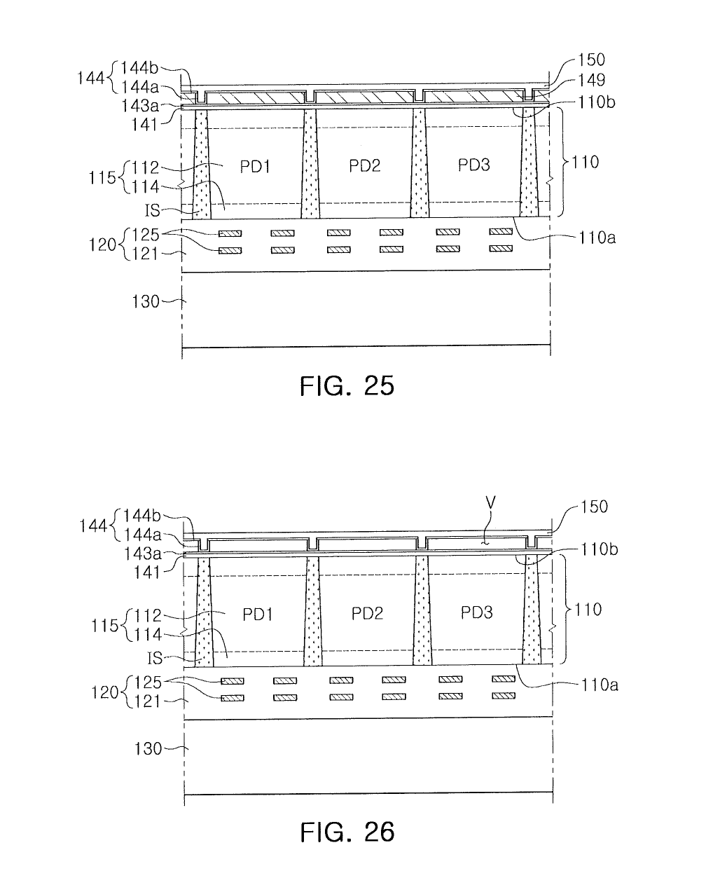

As illustrated in the previous example embodiment, the dummy pattern 149 may be removed, and then the TiO₂ layer may be formed. However, in this example embodiment, as illustrated in FIG. 25, the buffer layer 150 may be formed on the second lattice adjusting layer 144. The buffer layer 150 may be utilized to planarize a somewhat uneven surface of the TiO₂ layer caused by the dummy pattern 149.

As illustrated in FIG. 26, the space V, surrounded by the first and second lattice adjusting layers 143 and 144, may be provided by removing the dummy pattern 149.

As illustrated in the previous example embodiment, the first lattice adjusting layer 143 may be provided as the deposition surface for lattice matching, which is the lower surface of the first lattice adjusting layer 143, and the second lattice adjusting layer 144 may be provided as additional deposition surfaces for lattice matching, which are the upper surface and the lateral surfaces of the second lattice adjusting layer 144.

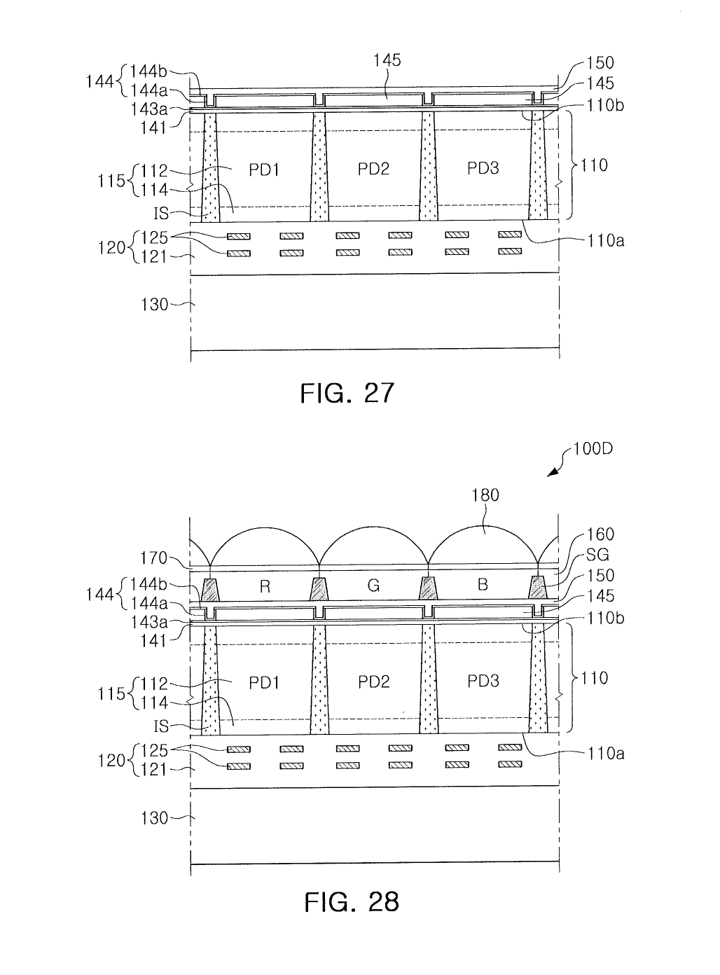

As illustrated in FIG. 27, a TiO₂ layer may be deposited in the space V surrounded by the first and second lattice adjusting layers 143 and 144. As indicated by an arrow in the figure, the first lattice adjusting layer 143 and the second lattice adjusting layer 144 may allow a rutile phase TiO₂ layer to be grown from the lower surface of the deposited TiO₂ layer and the lateral surfaces and the upper surface of the deposited TiO₂ layer by lattice matching.

A deposition source for the TiO₂ layer may be readily injected into the space V by appropriately designing the mask patterns M. The mask patterns M may be formed such that the deposition source for the TiO₂ layer may be easily supplied to the space V, and the unit pixels P may be connected to form columns or rows, while the mask patterns M may provide a source supply path through a lateral surface of a wafer in the process of depositing the TiO₂ layer.

As illustrated in FIG. 28, an image sensor 100D according to an example embodiment may be manufactured by sequentially forming the color filter layer 160, the planarizing layer 170, and the microlens layer 180.

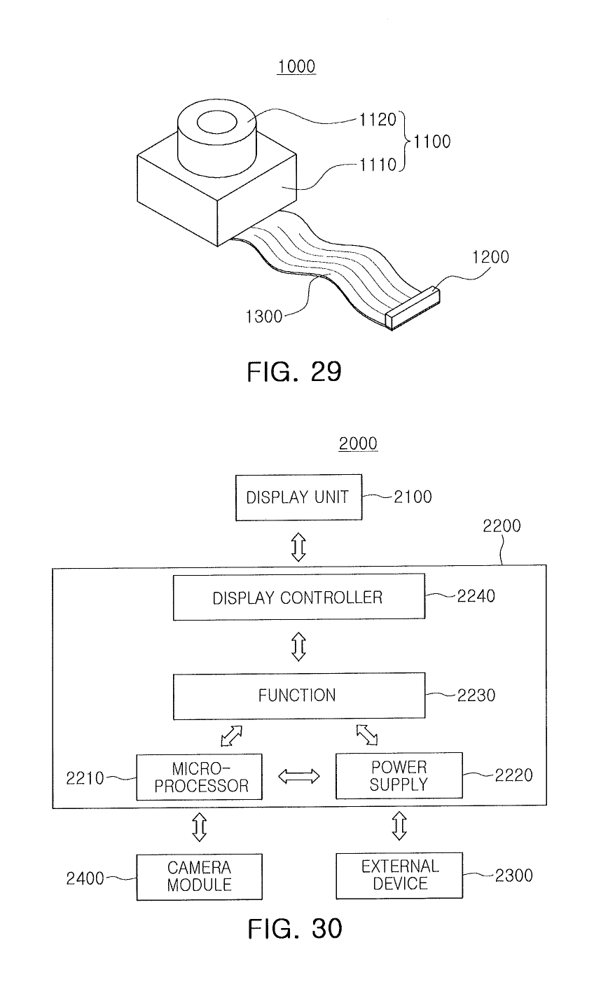

FIG. 29 is a schematic perspective view of an example embodiment of a camera module, including an image sensor, in accordance with principles of inventive concepts.

Referring to FIG. 29, a camera module 1000 may include a body 1100, an external terminal 1200, and a printed circuit board (PCB) 1300. The body 1100 may include an image processor 1110 and a lens unit 1120. The image processor 1110 may include an image sensor, according to an example embodiment.

FIG. 30 is a schematic diagram of an example embodiment of a mobile system including an image sensor, in accordance with principles of inventive concepts.

Referring to FIG. 30, a mobile system 2000 may include a display unit 2100, a body unit 2200, an external apparatus 2300, and a camera module 2400. The body unit 2200 may include a microprocessor 2210, a power supply 2220, a function 2230, and a display controller 2240.

The display unit 2100 may be electrically connected to the body unit 2200. The display unit 2100 may be electrically connected to the display controller 2240 of the body unit 2200. The display unit 2100 may display an image processed by the display controller 2240 of the body unit 2200.

The body unit 2200 maybe a system board or a mother board including a PCB, for example. The microprocessor 2210, the power supply 2220, the function 2230, and the display controller 2240 may be embedded or mounted on the body unit 2200.

The microprocessor 2210 may receive a voltage from the power supply 2220 to control the function 2230 and the display controller 2240. The power supply 2220 may receive a certain level of voltage from an external power source or the like, may divide the received level of voltage into various levels of voltages, and may supply the divided levels of voltages to the microprocessor 2210, the function 2230, and the display controller 2240.

The power supply 2220 may include a power management IC (PMIC). The PMIC may efficiently supply a voltage to the microprocessor 2210, the function module 2230, and the display controller 2240.

The function module 2230 may perform various functions of the mobile system 2000. For example, the function module 2230 may include various types of components that may perform a wireless communications function, such as an image output to the display unit 2100 or an audio output to a speaker, through dialing, or communications with the external apparatus 2300. For example, the function module 2230 may function as an image processor of the camera module 2400 and may include any combination of firmware, software, and hardware.

When the mobile system 2000 is connected to a memory card or the like for expansion of capacity, the function module 2230 may serve as a memory card controller. When mobile system 2000 further includes a universal serial bus (USE) for the expansion of function, the function module 2230 may operate as an interface controller.

The camera module 2400 may include an image sensor, according to an example embodiment. Thus, reliability of the mobile system 2000 may be increased.

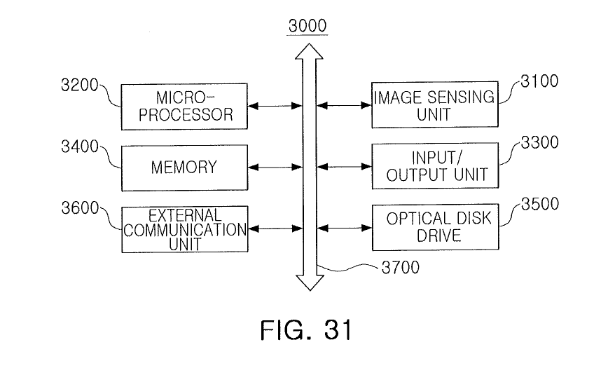

FIG. 31 is a schematic diagram of an electronic system including an image sensor according to an example embodiment of the present inventive concept.

Referring to FIG. 31, an electronic system 3000 may include an image sensing unit 3100, a microprocessor 3200, an input/output (I/O) unit 3300, a memory 3400, and a bus 3700.

The image sensing unit 3100 may generate a signal according to incident light, and may transfer the generated signal to the microprocessor 3200. The microprocessor 3200 may program and control the electronic system 3000. The I/O unit 3300 may perform data communications using the bus 3700. The I/O unit 3300 may input data to the electronic system 3000, or may output data from the electronic system 3000. The memory 3400 may store codes for booting of the microprocessor 3200, data processed by the microprocessor 3200, or externally input data. The memory 3400 may include a controller and a memory. The image sensing unit 3100, the microprocessor 3200, the I/O unit 3300, and the memory 3400 may communicate with each other through the bus 3700.

The electronic system 3000 may further include an optical disk drive (ODD) 3500 and an external communications unit 3600. The ODD 3500 may include, for example, a compact disk-read only memory (CD-ROM) drive or a digital versatile disk (DVD) drive. The external communications unit 3600 may include a modem, a local area network (LAN) card, or a USB port, and may also include an external memory, a wireless broadband internet (WiBro) communications device, or an infrared communications device.

The image sensing unit 3100 may include an image sensor according to an example embodiment. Accordingly, the utility and reliability of the image sensing unit 3100 included in the electronic system 3000 may be increased, for example, through inclusion of an anti-reflective coating in accordance with principles of inventive concepts.

As set forth above, according to example embodiments of the present inventive concept, a high-sensitivity image sensor may be provided without damage to other components, such as a wiring layer, while providing an anti-reflective layer having a high level of transmittance by employing a high-refractive-index optical layer capable of low-temperature growth.

While exemplary embodiments have been shown and described above, it will be apparent to those skilled in the art that modifications and variations could be made without departing from the scope of the present inventive concept, as defined by the appended claims.

What is claimed is:

1. An image sensor comprising:
a semiconductor layer having a first surface, a second surface opposing the first surface, and a plurality of photoelectric conversion units configured to receive light from the second surface;
an interconnecting layer disposed on the first surface of the semiconductor layer;
an anti-reflective layer having a first layer disposed on the second surface of the semiconductor layer, the first layer having a first refractive index, a second layer disposed on the first surface, the second layer having a second refractive index higher than the first refractive index, wherein the second layer is formed of a rutile phase TiO₂ layer, and a lattice adjusting layer contacting at least one of an upper surface and a lower surface of the second layer and includes at least one selected from a group consisting of SnO₂, MoO₃, and Sb₂O₃;
a buffer layer disposed on the anti-reflective layer; and
a plurality of color filters disposed on the buffer layer.

2. The image sensor of claim 1, wherein the lattice adjusting layer is disposed in a space between the first layer and the second layer so as to contact the lower surface of the second layer.

3. The image sensor of claim 1, wherein the lattice adjusting layer comprises a first lattice adjusting layer disposed on the lower surface of the second layer, and a second lattice adjusting layer disposed on the upper surface of the second layer.

4. The image sensor of claim 1, wherein the lattice adjusting layer comprises a plurality of lattice adjusting layers, the second layer is provided as a plurality of second layers, and the plurality of lattice adjusting layers and the plurality of second layers are alternately stacked.

5. The image sensor of claim 1, wherein the anti-reflective layer further comprises a lateral lattice adjusting layer contacting a lateral surface of the second layer.

6. The image sensor of claim 5, wherein the lateral lattice adjusting layer comprises at least one selected from a group consisting of SnO₂, MoO₃, Sb₂O₃, and RuO₂.

7. The image sensor of claim 1, wherein the first layer comprises a metal oxide or a metal fluoride including at least one metal selected from a group consisting of hafnium (HF), zirconium (Zr), aluminum (Al), tantalum (Ta), titanium (Ti), yttrium (Y), and lanthanum (La).

8. The image sensor of claim 1, wherein the first layer comprises Al₂O₃, and the lattice adjusting layer comprises SnO₂.

9. The image sensor of claim 1, wherein the first layer has a thickness of from about 1 nm to about 50 nm, and the second layer has a thickness of from about 20 nm to about 100 nm.

10. The image sensor of claim 9, wherein the lattice adjusting layer has a thickness of from about 0.5 nm to about 5 nm.

11. The image sensor of claim 1, wherein the anti-reflective layer has a light transmittance of 98% or more of the visible spectrum.

12. The image sensor of claim 1, wherein the buffer layer comprises at least one selected from a group consisting of SiO₂, SiON, Al₂O₃, HfO₂, Ta₂O₅, and ZrO₂.

13. An image sensor comprising:
a semiconductor layer having a plurality of pixel regions, each of the plurality of pixel regions having a photoelectric conversion unit formed therein;
an anti-reflective layer disposed on the semiconductor layer; and
a plurality of color filters disposed on the anti-reflective layer, and disposed on the plurality of pixel regions, respectively,
wherein the anti-reflective layer comprises a high-refractive-index optical layer disposed on the semiconductor layer including a TiO₂ layer having a refractive index of 2.6 or more, and a lattice adjusting layer contacting a surface of the high-refractive-index optical layer and including crystals, each of the crystals having a lattice constant closer to a lattice constant of a rutile phase TiO₂ layer than to a lattice constant of an anatase phase TiO₂ layer.

14. The image sensor of claim 13, wherein the anti-reflective layer further comprises a fixed charge layer disposed in a space between the high-refractive-index optical layer and the semiconductor layer, and including an Al₂O₃ layer.

15. The image sensor of claim 14, wherein the fixed charge layer has a thickness of from about 1 nm to about 15 nm, and the high-refractive-index optical layer has a thickness of from about 40 nm to about 60 nm.

16. A pixel array comprising:
an array of microlenses;
an array of photodetectors;
an array of color filters, wherein the array of microlenses concentrate incoming light through respective filters in the array of color filters to respective photodetectors in the array of photodetectors; and
an anti-reflective layer between the photodetectors and color filters, the anti-reflective layer including a first layer having a first index of refraction, a second layer closer to the color filter than the first layer having a second, higher, index of refraction, and a lattice adjusting layer between the first and second layers, wherein the second layer includes a rutile phase TiO₂ layer and the lattice adjusting layer includes a crystalline material having a lattice constant similar to that of the rutile phase TiO₂ layer.

17. The pixel array of claim 16, wherein the first layer includes one from the group of: a metal oxide or metal fluoride.

18. The pixel array of claim 16, wherein the lattice adjusting layer includes one from the group of: SnO₂, MoO₃, Sb₂O₃ and RuO₂.

19. The pixel array of claim 16, wherein the rutile phase TiO2 in the second layer has a refractive index of about 2.78.

20. The pixel array of claim 16, wherein the first layer comprises Al₂O₃, and the lattice adjusting layer comprises SnO₂.
